(19) United States
(12) Patent Application Publication
(10) Pub. No.: US 2014/0212705 A1
(43) Pub. Date: Jul. 31, 2014

(54) SOLID DYE SENSITIZATION TYPE SOLAR CELL AND SOLID DYE SENSITIZATION TYPE SOLAR CELL MODULE

(71) Applicants: Tamotsu Horiuchi, Shizuoka (JP); Tohru Yashiro, Kanagawa (JP); Hiroshi Deguchi, Kanagawa (JP); Hisamitsu Kamezaki, Kanagawa (JP); Takumi Yamaga, Kanagawa (JP); Keiichiroh Yutani, Kanagawa (JP); Yuko Arizumi, Kanagawa (JP)

(72) Inventors: Tamotsu Horiuchi, Shizuoka (JP); Tohru Yashiro, Kanagawa (JP); Hiroshi Deguchi, Kanagawa (JP); Hisamitsu Kamezaki, Kanagawa (JP); Takumi Yamaga, Kanagawa (JP); Keiichiroh Yutani, Kanagawa (JP); Yuko Arizumi, Kanagawa (JP)

(73) Assignee: RICOH COMPANY, LTD., Tokyo (JP)

(21) Appl. No.: 14/155,534

(22) Filed: Jan. 15, 2014

(30) Foreign Application Priority Data
Jan. 25, 2013 (JP) 2013-011708

(51) Int. Cl. H01G 9/20

(52) U.S. Cl. CPC H01G 9/2059
USPC 429/9; 136/254

(57) ABSTRACT

A solid dye sensitization type solar cell includes a substrate, a first electrode disposed on the substrate, an electron transport layer including an electron transport semiconductor and disposed on the first electrode, the electron transport layer including a photosensitizing compound adsorbed on a surface of the electron transport semiconductor, a hole transport layer disposed on the electron transport layer, and a second electrode disposed on the hole transport layer. Each of the first electrode and the second electrode includes divided multiple electrodes.

### CROSS-REFERENCE TO RELATED APPLICATIONS

This patent application is based on and claims priority pursuant to 35 U.S.C. §119 from Japanese Patent Application No. 2013-011708, filed on Jan. 25, 2013 in the Japan Patent Office, which is hereby incorporated by reference herein in its entirety.

### BACKGROUND

1. Technical Field

Exemplary embodiments of the present disclosure generally relate to a solid dye sensitization type solar cell and a solid dye sensitization type solar cell module employing the solid dye sensitization type solar cell.

2. Related Art

Recently, the importance of a solar cell is ever-increasing as an alternative energy to fossil fuel and a measure against global warming. However, the cost of present solar cells as typified by a silicon-based solar cell is high and is a factor impeding widespread use.

Thus, various low cost type solar cells are in research and development. Among the various low cost type solar cells, practical realization of a dye sensitization type solar cell announced by Graetzel et al, of École Polytechnique Fédérate de Lausanne is highly anticipated (disclosed in JP Patent No. 2664194; Nature, 353(1991)737; and J. Am. Chem. Soc., 115(1993)6382). The dye sensitization type solar cell includes a porous metal oxide semiconductor electrode on a transparent conductive glass substrate, a dye adsorbed on the surface of the porous metal oxide semiconductor electrode, an electrolyte having a reduction-oxidation pair, and a counter electrode. Graetzel et al. significantly enhanced photoelectric conversion efficiency by making porous the metal oxide semiconductor electrode such as titanium oxide and enlarging surface area, and conducting monomolecular adsorption of ruthenium complex as the dye. In addition, printing methods may be applied as manufacturing methods of an element. Thus, there is no need for expensive manufacturing equipment and manufacturing cost may be lowered. However, the dye sensitization type solar cell includes a volatile solvent. Accordingly, problems of decline in electric power generation efficiency due to degradation of iodine redox, and volatilization or leakage of an electrolytic solution are seen.

To compensate for the above-described problems, a completely solid dye sensitization type solar cell is disclosed. Specific examples of the completely solid dye sensitization type solar cell are as follows: 1) a completely solid dye sensitization type solar cell employing an inorganic semiconductor (disclosed in Semicond. Sci. Technol., 10(1995); and Electrochemistry, 70(2002)432), 2) a completely solid dye sensitization type solar cell employing a low molecular weight organic hole transport material (disclosed in JP-11-144773-A; Synthetic Metals, 89(1997)215; and Nature, 398(1998)583), and 3) a completely solid dye sensitization type solar cell employing a conductive polymer (disclosed in JP-2000-106223-A; and Chem. Lett., (1997)471).

The completely solid dye sensitization type solar cell disclosed in Semicond. Sci. Technol., 10(1995) employs copper iodide as material for a p-type semiconductor layer. The completely solid dye sensitization type solar cell disclosed in Semicond. Sci. Technol., 10(1995) exhibits comparatively good photoelectric conversion efficiency immediately after manufacture though after a few hours photoelectric conversion efficiency is halved due to an increase of crystal grains of copper iodide. The completely solid dye sensitization type solar cell disclosed in Electrochemistry, 70(2002)432 adds imidazoliniumthiocyanate to inhibit the crystalization of copper iodide though is insufficient.

The completely solid dye sensitization type solar cell employing the low molecular weight organic hole transport material is announced by Hagen et al. in Synthetic Metals, 89(1997)215, and is modified by Graetzel et al. in Nature, 398(1998)583. The completely solid dye sensitization type solar cell disclosed in JP-H11-144773-A employs a triphenylamine compound and includes forming a charge transport layer by vacuum deposition of the triphenylamine compound. As a result, the triphenylamine compound does not reach porous holes inside of a porous semiconductor and low photoelectric conversion efficiency is obtained. The completely solid dye sensitization type solar cell disclosed in Nature, 398(1998)583 includes dissolving a hole transport material of a spiro type in an organic solvent, and obtaining a composite body of nano titania particles and the hole transport material by employing spin coating. However, an optimal value of the film thickness of nano titania particles is approximately 2μm and is extremely thin compared to a film thickness of approximately 10 to approximately 20μm in a case in which an iodine electrolytic solution is employed. Thus, the amount of a dye adsorbed on titanium oxide is small, and sufficient light absorption or sufficient carrier generation is difficult. Accordingly, the properties of the completely solid dye sensitization type solar cell disclosed in Nature, 398(1998)583 fall short of a completely solid dye sensitization type solar cell employing an electrolytic solution. The disclosed reason that the film thickness of nano titania particles is approximately 2μm is if the nano titania particle film thickness becomes too thick, permeation of a hole transport material becomes insufficient.

The completely solid dye sensitization type solar cell employing the conductive polymer is announced by Yanagida et al. of Osaka University in Chem. Lett, (1997)471 and employs polypyrrole. The completely solid dye sensitization type solar cell employing the conductive polymer has low photoelectric conversion efficiency. The completely solid dye sensitization type solar cell employing polythiophene derivative disclosed in JP-2000-106223-A includes providing a charge transport layer on a porous titanium oxide electrode having adsorbed dye by employing an electrolytic polymerization method. However, problems of desorption of the dye from the titanium oxide or decomposition of the dye are seen. In addition, durability of the polythiophene derivative is a problem.

An open-circuit voltage obtained from a single cell of the dye sensitization type solar cell is approximately 0.7 V. Actual driving of a device with the open-circuit voltage of 0.7 V is insufficient. Thus, multiple cells are connected in series to increase the open-circuit voltage so that the device can be driven. Specific examples of a method of series connection include W-type disclosed in JP-H8-306399-A, Z-type disclosed in JP-2007-12377-A, and monolithic type disclosed in JP-2004-303463-A.

The W-type arranges adjacent cells in art alternating order of a positive electrode of a cell and a negative electrode of an adjacent cell, provides a common collecting electrode between adjacent cells, provides partition walls between the positive electrode plate and the negative electrode plate, and injects and seals an electrolytic solution. The W-type is comparatively easy to manufacture. However, due to arranging of adjacent cells in an alternating order of the positive electrode of a cell and the negative electrode of an adjacent cell, a cell area of the negative electrode that absorbs light is halved on both sides. Thus, irrespective to the side of a substrate that is subjected to incident light, only half of cells (i.e., cell area of the negative electrode that absorbs light) are subjected to incident light. Due to arranging of adjacent cells in an alternating order of the positive electrode of a cell and the negative electrode of an adjacent cell, non-functional cells exist alternately.

On the other hand, the Z-type arranges a positive electrode of all cells or a negative electrode of all cells on one side of a substrate, and connects terminals of adjacent cells by forming wiring via partition walls between cells. In the Z-type, due to arranging the negative electrode of all cells on one side of the substrate, all of the arranged cells function when the negative electrode side is subjected to incident light. Thus, unlike the W-type, photoelectric conversion efficiency does not decline in the Z-type.

In the Z-type, a positive electrode and an adjacent negative electrode are connected via partition walls. A conduction part is formed within the partition walls. The conduction part needs to be protected from a highly corrosive electrolytic solution. Manufacturing the partition walls with the conduction part is technically difficult. In addition, there is a need for a precision sealing technology to prevent leakage of the electrolytic solution or shorting. Particularly, when manufacturing a module with fine cells, a further advanced fine processing technology and precision sealing technology are necessary. However, completely preventing leakage of the electrolytic solution or shorting is difficult. Thus, decline in power yield and decline of properties of the dye sensitization type solar cell is often generated.

A dye sensitization type solar cell module disclosed in JP-2004-303463-A has a configuration called the monolithic type which is an advanced configuration of the Z-type. Unit cells are arranged on a single substrate and adjacent unit cells are electrically connected. The monolithic type has the same problems as the Z-type.

In a module having a configuration of the monolithic type or the Z-type, there is a need to make a cell completely independent from an adjacent cell. Thus, partition walls are provided between cells to divide cells. Accordingly, there is a problem of an increase in manufacturing processes and a problem of an aperture ratio of the module becoming small. To increase the aperture ratio, there is a need to make the partition walls narrower. Thus, manufacturing processes become more complicated and when configuring into a module, a problem of decline in power yield occurs.

On the other hand, there is a simple method of configuring a module that includes painting solid a transparent electrode, a counter electrode, and a Titania film; and wiring a metal grid to decrease resistance of the transparent electrode. However, the simple method enlarges an area of a single cell and an open-circuit voltage obtained from a single cell is approximately 0.7 V and is low. Actual driving of a device with the open-circuit voltage of 0.7 V is insufficient.

The amount of electric power generation of a solar cell is dependent on the amount of light. In addition, obtaining electric power at night is not possible. Thus, there is a need to store electric power during the day. A combination of an amorphous silicon solar cell and a secondary battery is disclosed in JP-H8-330616-A as an example of a combination of a solar cell and a secondary battery. The amorphous silicon solar cell and the secondary battery are connected in parallel. To adjust output voltage of the system as a whole, there is a need to adjust the number of connections of cells (number of cell stages) in the amorphous silicon solar cell and the secondary battery. Accordingly, configuration of a module becomes complex.

Thus, considered dye sensitization type solar cells and modules employing the considered dye sensitization type solar cells are unsatisfactory.

### SUMMARY

In view of the foregoing, in an aspect of this disclosure, there is provided a novel solid dye sensitization type solar cell including a substrate, a first electrode disposed on the substrate, an electron transport layer including an electron transport semiconductor and disposed on the first electrode, the electron transport layer including a photosensitizing compound adsorbed on a surface of the electron transport semiconductor, a hole transport layer disposed on the electron transport layer, and a second electrode disposed on the hole transport layer. Each of the first electrode and the second electrode includes divided multiple electrodes.

The aforementioned and other aspects, features, and advantages will be more fully apparent from the following detailed description of illustrative embodiments, the accompanying drawings, and associated claims.

### BRIEF DESCRIPTION OF THE DRAWINGS

The aforementioned and other aspects, features, and advantages of the present disclosure would be better understood by reference to the following detailed description when considered in connection with the accompanying drawings, wherein:

FIG. 1 is a cross-sectional view of a configuration of a solid dye sensitization type solar cell according to an embodiment of the present invention;

FIG. 2 is a cross-sectional view of a configuration of another solid dye sensitization type solar cell according to an embodiment of the present invention;

FIG. 3 is a cross-sectional view of a configuration of a combination of a solid dye sensitization type solar cell according to an embodiment of the present invention and a secondary battery;

FIG. 4 is a schematic view of a state after an etching process of an ATO substrate;

FIG. 5 is a schematic view of a state after forming a porous titanium oxide film serving as an electron transport layer on a compact electron transport layer;

FIG. 6 is a schematic view of a state after forming a first hole transport layer and a second hole transport layer;

FIG. 7 is a schematic view of a state after deposition of gold; and

FIG. 8 is a schematic view of a state after coating silver paste.

The accompanying drawings are intended to depict exemplary embodiments of the present disclosure and should not be interpreted to limit the scope thereof. The accompanying drawings are not to be considered as drawn to scale unless explicitly noted.

### DETAILED DESCRIPTION

In describing embodiments illustrated in the drawings, specific terminology is employed for the sake of clarity. However, the disclosure of this patent specification is not intended to be limited to the specific terminology so selected and it is to be understood that each specific element includes all technical equivalents that operate in a similar manner and achieve similar results,

In view of the foregoing, in an aspect of this disclosure, there is provided a novel solid dye sensitization type solar cell that is easy to manufacture and resolves the above-described problems.

Referring now to the drawings, exemplary embodiments of a solid dye sensitization type solar cell of the present invention are described in detail below.

### <Solar Cell Configuration>

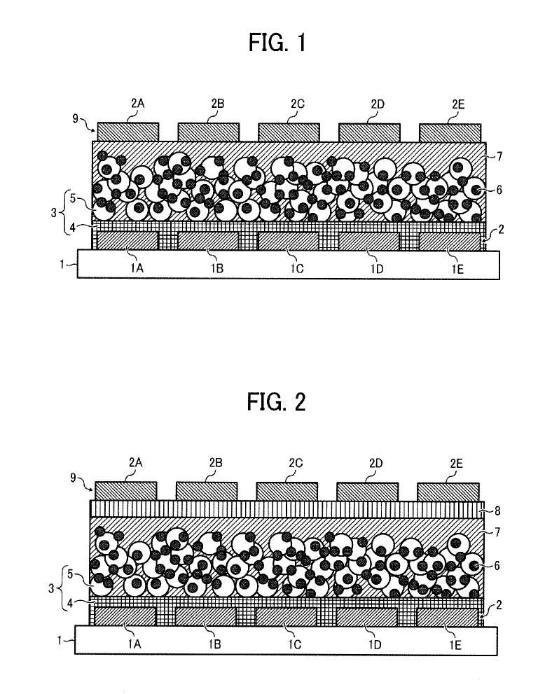

First, a configuration of a solid dye sensitization type solar cell according to an embodiment of the present invention is described with reference to FIG. 1 and FIG. 2.

FIG. 1 is a cross-sectional view of an example of the solid dye sensitization type solar cell.

The solid dye sensitization type solar cell is configured of a first electrode 2 provided on a substrate 1, an electron transport layer 3 formed of a compact electron transport layer 4 and a porous electron transport layer 5 provided on the first electrode 2 and the substrate, a photosensitizing compound 6 adsorbed on the porous electron transport layer 5, and a first hole transport layer 7 and a second electrode 9 provided on the electron transport layer 3 including the adsorbed photosensitizing compound 6.

FIG. 2 is a cross-sectional view of another example of the solid dye sensitization type solar cell.

Compared to FIG. 1, the example of FIG. 2 differs in having a second hole transport layer 8 between the first hole transport layer 7 and the second electrode 9.

### <First Eelectrode (Electron Collecting Electrode)>

The first electrode 2 is an electron collecting electrode. Materials for the first electrode 2 may be any material as long as the material is a conductive substance that is transparent with respect to visible light. Publicly known materials employed in normal photoelectric conversion elements and liquid panels may be employed. Specific examples of materials for the first electrode 2 include, but are not limited to, indium tin oxide (hereinafter referred to as ITO), fluorine-doped tin oxide (hereinafter referred to as FTO), antimony-doped tin oxide (hereinafter referred to as ATO), indium zinc oxide, niobium titanium oxide, and graphene. The above-described materials may be used alone or a plurality of the above-described materials may be laminated.

It is preferable that thickness of the first electrode 2 is in a range from approximately 5 nm to approximately 100 μm, and more preferably in a range from approximately 50 nm to approximately 10 μm.

In addition, to maintain a certain hardness of the first electrode 2, it is preferable that the first electrode 2 is provided on the substrate 1 formed of the material that is transparent with respect to visible light. Specific examples of materials for the substrate 1 include, but are not limited to, glass, transparent plastic plate, transparent plastic film, and inorganic transparent crystal substance.

Publicly known examples in which the first electrode 2 and the substrate 1 are integrated as one may also be employed. Specific examples of the first electrode 2 and the substrate 1 integrated as one include, but are not limited to, FTO coat glass, ITO coat glass, zinc oxide aluminum coat glass, FTO coat transparent plastic film, and ITO coat transparent plastic film.

Further, a transparent electrode having tin oxide or indium oxide doped with a differing valence cation or anion, and a metal electrode configured to allow light to pass through such as a mesh shape and a stripe shape may be employed on the substrate 1 such as a glass substrate. The above-described transparent electrode and the metal electrode may be used alone, used in a combination of two or more types, or two or more types may be laminated. In addition, a metal lead wire may be simultaneously employed to lower resistance. Specific materials of the metal lead wire include, but are not limited to, aluminum, copper, silver, gold, platinum, and nickel. When simultaneously employing the metal lead wire, the metal lead wire may be set on the substrate 1 by deposition, sputtering, and pressure joining and then providing ITO and FTO on the substrate 1 with the metal lead wire.

In an embodiment of the present invention, the first electrode 2 is divided into 1A, 1B, 1C, 1D, and 1E. Division methods include, but are not limited to, an etching method employing a laser or immersion in an etchant, and a division method employing a mask when vacuum film forming such as in sputtering.

### <Electron Transport Layer>

In the solid dye sensitization type solar cell according o an embodiment of the present invention, a thin film formed of a semiconductor serving as the electron transport layer 3 is formed on the above-described first electrode 2. It is preferable that the electron transport layer 3 has a laminated configuration in which the compact electron transport layer 4 is formed on the first electrode 2 and the porous electron transport layer 5 is formed on the electron transport layer 4.

The compact electron transport layer 4 is formed to prevent electron contact between the first electrode 2 and the second electrode 9. Thus, as long as the first electrode 2 and the second electrode 9 do not physically contact each other, a pinhole or crack is not a problem.

There is no restriction regarding film thickness of the compact electron transport layer 4 though it is preferable that film thickness is approximately 10 nm to approximately 1 μm, more preferably approximately 20 nm to approximately 700 nm.

The term “compact” in the compact electron transport layer 4 refers to a packing density of an inorganic oxide semiconductor being denser than a packing density of a semiconductor fine particulate in the porous electron transport layer 5.

The porous electron transport layer 5 formed on the compact electron transport layer 4 may be a single layer or a multilayer. In a case in which the porous electron transport layer 5 is a multilayer, the multilayer may be a multilayer coat of a dispersion liquid of the semiconductor fine particulate with different particle diameters, a multilayer coat of a different type of semiconductor, and a multilayer coat of a different composition resin and additive. Multilayer coating is effective in a case in which film thickness is insufficient with one coating.

Generally, as film thickness of the electron transport layer 3 increases, the carrying amount of the photosensitizing compound 6 per unit projection area increases and capture rate of light becomes high, however, diffusion length of injected electrons also increases and loss from charge recombination also becomes large. Therefore, film thickness of the electron transport layer 3 is preferably in a range from approximately 100 nm to approximately 100 μm.

There is no restriction regarding the above-described semiconductors and publicly known semiconductors may be used. Examples of the semiconductor include, but are not limited to, an element semiconductor such as silicon and germanium, a compound semiconductor such as a metal chalcogenide, and a compound having a perovskite structure.

Specific examples of the metal chalcogenide include, but are not limited to, an oxide or sulfide of titanium, tin, zinc, iron, tungsten, indium, yttrium, lanthanum, vanadium, and niobium; a sulfide of cadmium, zinc, lead, silver, antimony, and bismuth; a selenide of cadmium or lead; and a telluride of cadmium.

Preferable examples of the compound semiconductor include, but are not limited to, a phosphide of zinc, gallium, indium, and cadmium; gallium arsenide; copper-indium-selenide; and copper-indium-sulfide.

Preferable examples of the compound having the perovskite structure include, but are not limited to, strontium titanate, calcium titanate, sodium titanate, barium titanate, and potassium niobate.

Among the above-described examples of semiconductors, oxide semiconductors are preferable. Particularly, titanium oxide, zinc oxide, tin oxide, and niobium oxide are preferable. The above-described particularly preferable semiconductors may be used alone or in a combination of two or more types.

There is no restriction regarding crystal form of the above-described semiconductors and the crystal form may be single crystal, polycrystal, or amorphous.

There is no restriction regarding size of the semiconductor fine particulate though it is preferable that an average particle diameter of a primary particle is in a range from approximately 1 nm to approximately 100 nm, and more preferably in a range from approximately 5 nm to approximately 50 nm.

In addition, by combining or laminating a semiconductor fine particulate having a larger average particle diameter, efficiency of the electron transport layer 3 may be increased by an effect of scattering incident light. In a case of combining or laminating the semiconductor fine particulate having the larger average particle diameter, it is preferable that the average particle diameter of the semiconductor fine particulate having the larger average particle diameter is in a range from approximately 50 nm to approximately 500 nm.

There is no restriction regarding manufacturing methods of the electron transport layer 3 and may be a method of forming a thin film in a vacuum such as sputtering or a wet-type film forming method.

Considering manufacturing cost, the wet-type film forming method is preferable. A method in which a paste having a sol or powder of the semiconductor fine particulate dispersed is prepared, and coating the prepared paste onto the first electrode 2 and substrate 1 is preferable.

In a case of employing the wet-type film forming method, there is no restriction regarding coating methods and publicly known methods may be employed. Specific examples of coating methods include, but are not limited to, dip coating method, spray coating method, wire bar coating method, spin coating method, roll coating method, blade coating method, and gravure coating. Additionally, various wet-type printing methods may be employed such as relief printing, offset printing, gravure printing, intaglio printing, rubber plate printing, and screen printing.

In a case of manufacturing a dispersion liquid by mechanical pulverization or by employing a mill, the semiconductor fine particulate may be dispersed alone in water or an organic solvent, or a combination of the semiconductor fine particulate and a resin may be dispersed in water or an organic solvent.

Specific examples of the resin include, but are not limited to, polymers or copolymers of vinyl compounds (e.g., styrene, vinyl acetate, acrylic ester, methacrylic ester), silicone resin, phenoxy resin, polysulfone resin, polyvinyl butyral resin, polyvinyl formal resin, polyester resin, cellulose ester resin, cellulose ether resin, urethane resin, phenol resin, epoxy resin, polycarbonate resin, polyarylate resin, polyamide resin, and polyimide resin.

Specific examples of a solvent in which the semiconductor fine particulate are dispersed include, but are not limited to, water, alcohol-based solvents (e.g., methanol, ethanol, isopropyl alcohol, α-terpineol), ketone-based solvents (e.g., acetone, methyl ethyl ketone, methyl isobutyl ketone), ester-based solvents (e.g., ethyl formate, ethyl acetate, n-butyl acetate), ether-based solvents (e.g., diethyl ether, dimethoxyethane, tetrahydrofuran, dioxolane, dioxane), amide-based solvents (e.g.; N,N-dimethylformamide; N,N-dimethyacetamide; N-methyl-2-pyrrolidone), halogenated hydrocarbon-based solvents (e.g., dichloromethane, chloroform, bromoform, methyl iodide, dichloroethane, trichloroethane, trichloroethylene, chlorobenzene, o-dichlorobenzene, fluorobenzene, bromobenzene, iodobenzene, l-chloronaphthalene), and hydrocarbon-based solvents (e.g., n-pentane; n-hexane; n-octane; 1,5-hexadiene; cyclohexane; methylcyclohexane; cyclohexadiene; benzene; toluene; o-xylene; m-xylene; p-xylene; ethylbenzene; cumene).

The above-described solvents may be used alone or in a combination of two or more types.

An acid (e.g., hydrochloric acid, nitric acid, acetic acid), a surface-active agent (e.g., polyoxyethylene (10) octyl phenyl ether), and a chelating agent (e.g., acetylacetone, 2-aminoethanol, ethylenediamine) may be added to the dispersion liquid of the semiconductor fine particulate or the paste of the semiconductor fine particulate obtained with a sol-gel method to prevent re-agglomeration of the semiconductor fine particulate.

In addition, a thickener may be added to enhance film forming. Specific examples of the thicknener include, but are not limited to, polymers such as polyethylene glycol and polyvinyl alcohol, and ethyl cellulose.

After coating the semiconductor line particulate onto the first electrode 2 and substrate 1, it is preferable that the semiconductor fine particulate is subjected to a process of firing, microwave irradiation, electron beam irradiation, and laser irradiation to electronically contact particles of the semiconductor fine particulate with each other, enhance film strength, and enhance adhesion of the semiconductor fine particulate with the first electrode 2 and substrate 1. The above-described processes may be conducted alone or in a combination of two or more types.

In a case of firing, there is no restriction regarding firing temperature range. However, if firing temperature is too high, the resistance of the substrate 1 may become high or the substrate 1 may melt. Thus, it is preferable that firing temperature range is approximately 30° C. to approximately 700° C., and more preferably approximately 100° C. to approximately 600° C. In addition, there is no restriction regarding firing time. Preferably, firing time is approximately 10 minutes to approximately 10 hours.

To increase a surface area of the semiconductor fine particulate, or enhance an electron injection rate from the photosensitizing compound 6 to the semiconductor fine particulate the following plating may be conducted after firing the semiconductor fine particulate. A chemical plating may be conducted employing, for example, an aqueous solution of titanium tetrachloride or a mixed solution with an organic solvent, Alternatively, an electrochemical plating may be conducted employing an aqueous solution of titanium trichloride.

The microwave irradiation may be irradiated from a side at which the electron transport layer 3 is formed or from a backside of the formed electron transport layer 3.

There is no restriction regarding irradiation time. Preferably, irradiation time is approximately 1 hour or less.

A film formed of the semiconductor fine particulate having a diameter of a few dozen nm laminated by sintering is porous.

A nano-porous structure has an extremely large surface area and the extremely large surface area can be represented as a roughness factor.

The roughness factor is a value representing actual internal area of a porous structure with respect to an area of the semiconductor fine particulate coated on the first electrode 2 and substrate 1. Accordingly, a large roughness factor is preferable. However, in relation to the preferable film thickness of the electron transport layer 3, the roughness factor is preferably 20 or more.

### <Photosensitizing Compound (Dye)>

According to an embodiment of the present invention, the photosensitizing compound 6 is adsorbed on the surface of a semiconductor of the porous electron transport layer 5 to further enhance photoelectric conversion efficiency of the solid dye sensitization type solar cell. Specific examples of the photosensitizing compound 6 include, but are not limited to, metal complex compounds (disclosed in JP-H07-500630-A; JP-H 10-233238-A; JP-2000-26487-A; JP-2000-323191-A; JP-2001-59062-A), coumarin compounds (disclosed in JP-H10-93118-A; JP-2002-164089-A; JP-2004-95450; J. Phys. Chem. C, 7224, Vol. 111(2007)), polyene compounds (disclosed in JP-2004-95450-A; Chem. Commun., 4887(2007)), indoline compounds (disclosed in JP-2003-264010-A; JP-2004-63274-A; JP-2004-115636-A; JP-2004-200068-A; JP-2004-235052-A; J. Am. Chem. Soc., 12218, Vol. 126(2004); Chem. Commun., 3036(2003); Angew. Chem. Int. Ed., 1923, Vol. 47(2008)), thiophene compounds (disclosed in J. Am. Chem. Soc., 16701, Vol. 128(2006); and J. Am. Chem. Soc., 14256, Vol. 128(2006)), cyanine dyes (disclosed in JP-H11-86916-A; JP-H11-214730-A; JP-2000-106224-A; JP-2001-76773-A; JP-2003-7359-A), merocyanine dyes (disclosed in JP-H11-214731-A; JP-H11-238905-A; JP-2001-52766-A; JP-2001-76775-A; JP-2003-7360-A), 9-arylxanthene compounds (disclosed in JP-H10-92477-A; JP-H11-273754-A; JP-H11-273755-A; JP-2003-31273-A;), triarylmethane compounds (disclosed in JP-H10-93118-A; JP-2003-31273-A), phthalocyanine compounds (disclosed in JP-H09-199744-A; JP-H10-233238-A; JP-H11-204821-A; JP-H11-265738-A; J. Phys. Chem., 2342, Vol. 91(1987); J. Phys. Chem. B, 6272, Vol. 97(1993); Electroanal. Chem., 31, Vol. 537(2002); JP-2006-032260-A; J. Porphyrins Phthalocyanines, 230, Vol. 3(1999); Angew. Chem. Int. Ed., 373, Vol. 46(2007); Langmuir, 5436, Vol. 24(2008)), and porphyrin compounds.

Among the above-described examples of the photosensitizing compound 6, preferably, metal complex compounds, coumarin compounds, polyene compounds, indoline compounds, and thiophene compounds are employed.

Methods to adsorb the photosensitizing compound 6 on the porous electron transport layer 5 include a method of immersing the porous electron transport layer 5 having the semiconductor fine particulate in a solution of or a dispersion liquid of the photosensitizing compound 6; and a method of coating a solution of or a dispersion liquid of the photosensitizing compound 6 on the porous electron transport layer 5. Specific examples of the method of immersing include, but are not limited to, immersion method, dip method, roll method, and air knife method. Specific examples of the method of coating include, but are not limited to, wire bar coating method, slide hopper coating method, extrusion coating method, curtain coating method, spin coating method, and spray coating method.

In addition, adsorbing the photosensitizing compound 6 on the porous electron transport layer 5 may be conducted in a supercritical fluid such as carbon dioxide.

Further, when adsorbing the photosensitizing compound 6 on the porous electron transport layer 5, a condensing agent may be used. The condensing agent may be any condensing agent having a catalytic effect of bonding, physically or chemically, the photosensitizing compound 6 to a porous electron transport compound on an inorganic substance surface. Alternatively, the condensing agent may be any condensing agent stoichiometrically effecting advantageous chemical equilibrium transition. Furthermore, thiol or hydroxy compound serving as an auxiliary condensing agent may be added.

A solvent to melt or disperse the photosensitizing compound 6 may be the same as the above-described solvent to disperse the semiconductor fine particulate.

In addition, due to some types of the photosensitizing compound 6 working more effectively when agglomeration between compounds is inhibited, a co-adsorbent (agglomeration dissociation agent) may be used.

It is preferable that the co-adsorbent is a steroid compound (e.g., cholic acid, chenodeoxycholic acid), a long-chain alkyl carboxylic acid, or a long-chain alkyl phosphonic acid. The co-adsorbent is arbitrarily selected according to an employed dye. The addition amount of the co-adsorbent is preferably approximately 0.01 parts by weight to approximately 500 parts by weight, more preferably approximately 0.1 parts by weight to approximately 100 parts by weight, with respect to 1 part by weight of the employed dye.

It is preferable that the temperature is approximately −50° C. to approximately 200° C. when adsorbing the photosensitizing compound 6, or a combination of the photosensitizing compound 6 and the co-adsorbent, to the porous electron transport layer 5. The adsorbing may be conducted still standing or conducted while agitating.

There is no restriction regarding methods of agitating. Agitation may be conducted with a stirrer, a ball mill, a paint conditioner, a sand mill, an attritor, a disperser, and an ultrasonic disperser.

The adsorbing time is preferably approximately 5 seconds to approximately 1000 hours, more preferably approximately 10 seconds to approximately 500 hours, and most preferably approximately 1 minute to approximately 150 hours. It is preferable that adsorbing is conducted in a dark place.

### <Hole Transport Layer>

A hole transport layer according to an embodiment of the present invention may be a single layer configuration or a laminated layer configuration formed of multiple materials. In a case of the hole transport layer having the laminated layer configuration, it is preferable that a polymer material is employed for the second hole transport layer 8 adjacent to the second electrode 9. By employing the polymer material having good film forming capability, the surface of the porous electron transport layer 5 may be made smoother and photoelectric conversion property of the solid dye sensitization type solar cell according to an embodiment of the present invention may be further enhanced. In addition, it is difficult for the polymer material to permeate inside the porous electron transport layer 5. Thus, the polymer material is good for coating the surface of the porous electron transport layer 5. The polymer material also exhibits an effect of preventing short circuit when forming an electrode. As a result, higher performance of the solid dye sensitization type solar cell is obtained. A hole transport material employed for the hole transport layer having the single layer configuration is a publicly known hole transport compound. Specific examples of the hole transport compound include, but are not limited to, oxadiazole compounds (disclosed in JP-S34-5466-A), triphenylmethane compounds (disclosed in JP-S45-555-A), pyrazoline compounds (disclosed in JP-S52-4188-A), hydrazone compounds (disclosed in JP-S55-42380-A), oxadiazole compounds (disclosed in JP-S56-123544-A), tetraaryl benzidine compounds (disclosed in JP-S54-58445-A), stilbene compounds (disclosed in JP-S58-65440-A, JP-S60-98437-A), oligothiophene compounds (disclosed in JP-H8-264805-A), acene compounds having bonded alkylsilane (disclosed in J. Am. Che. Soc., 9482, Vol. 123(2002); Org. Lett., 15, Vol. 4(2002)), benzothieno[3,2-b]benzothiophene compounds (disclosed in J. Am. Chem. Soc., 5084, Vol. 126(2004); J. Am. Chem. Soc., 12604, Vol. 128(2006); J. Am. Chem. Soc., 15732, Vol. 129(2007)), precursor compounds such as pentacene, oligothiophene, and porphyrin in which a portion desorbs by heating (disclosed in J. Appl. Phys., 2136, Vol. 79(1996); Adv. Mater., 480, Vol. 11(1999); J. Am. Chem. Soc., 8812, Vol. 124(2002); J. Am. Chem. Soc., 1596, Vol. 126(2004); Appl. Phys. Lett., 2085, Vol. 84(2004)), heterocyclic and benzene ring condensed compounds such as dithienylbenzene and dithiazolylbenzene (disclosed in JP-2005-206750-A), acene compounds such as indoline compound tetracene and pentacene (disclosed in JP-H6-009951-A), and rubrene. Among the above-described examples, oligothiophene compounds, benzidine compounds, and stilbene compounds are particularly preferable when carrier mobility and ionization potential are taken into consideration. The oligothiophene compounds, benzidine compounds, and stilbene compounds may be used alone or in a combination of two or more types.

A publicly known hole transport polymer material is employed for the second hole transport layer 8 adjacent to the second electrode 9 in the hole transport layer having the laminated layer configuration. Specific examples of the hole transport polymer material include, but are not limited to, polythiophene compounds (e.g., poly(3-n-hexylthiophene), poly(3-n-octyloxythiophene), poly(9,9′-dioctyl-fluorene-co-bithiophene), poly(3,3′″-didodecyl-quarter thiophene), poly(3,6-dioctylthieno[3,2-b]thiophene), poly(2,5-bis(3-decylthiophene-2-yl)thieno[3,2-b]thiophene, poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), and poly(3,6-dioctylthieno[3,2-b]thiophene-co-bithiophene)), polyphenylene vinylene compounds (e.g., poly[2-methoxy-5-(2-ethylhexyloxy)-1,4-phenylenevinylene], poly[2-methoxy-5-(3,7-dimethyloctyloxy)-1,4-phenylenevinylene], and poly[2-methoxy-5-(2-ethylphexyloxy)-1,4-phenylenevinylene-co-(4,4′-phenylene-vinylene)]), polyfluorene compounds (e.g., poly(9,9′-didodecylfluorenyl-2,7-diyl), poly[(9,9-dioctyl-2,7-divinylenefluorene)-alt-co-(9,10-anthracene)], poly[(9,9-dioctyl-2,7-divinylenefluorene)-alt-co-(4,4′-biphenylene)], poly[(9,9-dioctyl-2,7-divinylenefluorene)-alt-co-(2-methoxy-5-(2-ethylhexyloxy)-1,4-phenylene)], and poly[(9,9-dioctyl-2,7-diyl)-co-(1,4-(2,5-dihexyloxy)benzene)D, polyphenylene compounds (e.g., poly[2,5-dioctyloxy-1,4-phenylene], and poly[2,5-di(2-ethylhexyloxy-1,4-phenylene], polyarylamine compounds (e.g., poly[(9,9-dioctylfluorenyl-2,7-diyl)-alt-co-(N,N′-diphenyl)-N,N′-di(p-hexylphenyl)- 1,4-diaminobenzene], poly[(9,9-dioctylfluorenyl-2,7-diyl)-alt-co-(N,N′-bis(4-octyloxyphenyl)benzidine-N,N′-(1,4-diphenylene)], poly[(N,N′-bis(4-octyloxyphenyl)benzidine-N,N′-(1,4-diphenylene)], poly[(N,N′-bis(4-(2-ethylhexyloxy)phenyl)benzidine-N,N′-(1,4-diphenylene)], poly[phenylimino-1,4-phenylenevinylene-2,5-dioctyloxy-1,4-phenylenevinylene-1,4-phenylene], poly[p-tolylimino-1,4-phenylenevinylene-2,5-di(2-ethylhexyloxy)-1,4-phenylenevinylene-1,4-phenylene], and poly[4-(2-ethylhexyloxy)phenylimino-1,4-biphenylene]), and polythiadiazole compounds (e.g., poly[(9,9-dioctylfluorenyl-2,7-diyl)-alt-co-(1,4-benzo(2,1′,3)thiadiazole], and poly[(3,4-didecylthiophene-co-(1,4-benzo(2,1′,3)thiadiazole]).

Among the above-described hole transport polymer materials, polythiophene compounds and polyarylamine compounds are particularly preferable when carrier mobility and ionization potential are taken into consideration. The polythiophene compounds and polyarylamine compounds may be used alone or in a combination of two or more types. By employing the polythiophene compounds and polyarylamine compounds, hole mobility becomes efficient and a solid dye sensitization type solar cell with better characteristics is obtained.

In addition, various additives may be added to the above-described hole transport material in the solid dye sensitization type solar cell according to an embodiment of the present invention.

Specific examples of the additives include, but are not limited to, metal iodides (e.g., iodine, lithium iodide, sodium iodide, potassium iodide, cesium iodide, calcium iodide, copper iodide, iron iodide, silver iodide), quaternary ammonium salts (e.g., tetraalkylammonium iodide, pyridinium iodide), metal bromides (e.g., lithium bromide, sodium bromide, potassium bromide, cesium bromide, calcium bromide), bromide salts of quaternary ammonium compounds (e.g., tetraalkylammonium bromide, pyridinium bromide), metal chlorides (e.g., copper chloride, silver chloride), metal acetates (e.g., copper acetate, silver acetate, palladium acetate), metal sulfates (e.g., copper sulfate, zinc sulfate), metal complexes (e.g., ferrocyanide acid salt-ferricyanide acid salt, ferrocene-ferricenium ion), sulfur compounds (e.g., sodium polysulfide, alkylthiol-alkyldisulfide), ion liquids (e.g., viologen dyes; hydroquinone; 1,2-dimethyl-3-n-propylimidazolinuim salt iodide; 1-methyl-3-n-hexylimidazolinuim salt iodide; 1,2-dimethyl-3-ethylimidazoliumtrifluoromethane sulfonic acid salt; 1-methyl-3-butylimidazoliumnonafluorobutyl sulfonic acid salt; 1-methyl-3-ethylimidazoliumbis(trifluoromethyl)sulfonylimide; 1-methyl-3-n-hexylimidazoliumbis(trifluoromethyl)sulfonylimide; 1-methyl-3-n-hexylimidazolium dicyanamide), basic compounds (e.g., pyridine, 4-t-butylpyridine, benzimidazol), and lithium compounds (e.g., lithium trifluoromethanesulfonylimide, lithium diisopropylimide). Among the above-described additives, ion liquids including bis(trifluoromethyl)sulfonylimide anion are particularly preferable.

The above-described additives may be used alone or in a combination of two or more types.

By employing the above-described additives, conductivity of the hole transport material is enhanced. As a result, a solid dye sensitization type solar cell with good photoelectric conversion efficiency is obtained.

In a solid dye sensitization type solar cell according to an embodiment of the present invention, an acceptor material may be further added according to need along with the above-described hole transport material or various additives.

Specific examples of the acceptor material include, but are not limited to, chloranil; bromanil; tetracyanoethylene; tetracyanoquinodimethane; 2,4,7-trinitro-9-fluorenone; 2,4,5,7-tetranitro-9-fluorenone; 2,4,5,7-tetranitro xanthone; 2,4,8-trinitro thioxanthone; 2,6,8-trinitro-4H-indeno[1,2-b]thiophene-4-one; 1,3,7-trinitro dibenzothiophene-5,5-dioxide; and diphenoquinone derivative.

The above-described acceptor materials may be used alone or in a combination of two or more types.

In addition, an oxidizing agent may be added to make a portion of the hole transport material a radical cation in order to enhance conductivity of the hole transport material.

Specific examples of the oxidizing agent include, but are not limited to, hexachloroantimonic acid tris(4-bromophenyl)aminium, silver hexafluoroantimonate, nitrosoniumtetrafluoroborate, and silver nitrate.

It is to be noted that all of the hole transport material does not need to be oxidized by the added oxidizing agent. Only a portion of the hole transport material needs to be oxidized by the added oxidizing agent. Further, the added oxidizing agent may be taken out or left in the hole transport material after addition.

The hole transport layer is formed directly onto the electron transport layer 3 including the photosensitizing compound 6. There is no restriction regarding manufacturing methods of the hole transport layer and may be a method of forming a thin film in a vacuum such as vacuum deposition or a wet-type film forming method. Considering manufacturing cost, the wet-type film forming method is particularly preferable. A method of coating the hole transport layer onto the electron transport layer 3 is preferable.

In a case of employing the wet-type film forming method, a solvent to melt or disperse the hole transport material or various additives may be the same as the above-described solvent to disperse the semiconductor fine particulate excluding the alcohol-based solvents.

There is no restriction regarding coating methods in the wet-type film forming method and publicly known methods may be employed. Various coating methods may be employed such as dip coating method, spray coating method, wire bar coating method, spin coating method, roll coating method, blade coating method, and gravure coating. Additionally, various wet-type printing methods may be employed such as relief printing, offset printing, gravure printing, intaglio printing, rubber plate printing, and screen printing.

In addition, film forming may be conducted in a supercritical fluid or a subcritical fluid.

There is no restriction regarding the supercritical fluid as long as the supercritical fluid exists as a non-agglomerating high density fluid at temperatures and pressures beyond a critical point in which a fluid may coexist as a gas or a liquid, and the non-agglomerating high density fluid is in a state above critical temperature, above critical pressure, and does not agglomerate when compressed. The supercritical fluid may be selected according to objective though it is preferable that the supercritical fluid has a low critical temperature.

It is preferable that the supercritical fluid is, for example, carbon monoxide, carbon dioxide, ammonia, nitrogen, water, alcohol-based solvents (e.g., methanol, ethanol, n-butanol), hydrocarbon-based solvents (e.g., ethane, propane, 2,3-dimethylbutane, benzene, toluene), halogen-based solvents (e.g., methylene chloride, chlorotrifluoromethane), and ether-based solvents (e.g., dimethyl ether). Among the above-described examples of the supercritical fluid, carbon dioxide is particularly preferable. Carbon dioxide has a critical pressure of 7.3 MPa and a critical temperature of 31° C. that makes a creation of a supercritical state easy. In addition, carbon dioxide is incombustible and is easy to handle.

The above-described examples of the supercritical fluid may be used alone or n a combination of two or more types.

There is no restriction regarding the subcritical fluid as long as the subcritical fluid exists as a high pressure fluid at temperatures and pressures around a critical point. The subcritical fluid may be selected according to objective. The above-described solvents in the examples of the supercritical fluid may also be employed as the subcritical fluid. The above-described solvents in the examples of the supercritical fluid are preferable.

There is no restriction regarding the critical temperature and the critical pressure of the supercritical fluid. The critical temperature and the critical pressure may be selected according to objective. The critical temperature is preferably in a range from approximately −273° C. to approximately 300° C., and more preferably in a range from approximately 0° C. to approximately 200° C.

An organic solvent or an entrainer may be added and used with the above-described supercritical fluid and subcritical fluid. By adding the organic solvent or the entrainer, solubility of the hole transport material or various additives in the supercritical fluid can be easily adjusted.

There is no restriction regarding the organic solvent and may be selected according to objective. The organic solvent may be the same as the above-described solvent to disperse the semiconductor fine particulate excluding the alcohol-based solvents.

After providing the electron transport layer 3 having adsorbed photosensitizing compound 6 and the first hole transport layer 7 onto the first electrode 2, a press treatment may be conducted. By conducting the press treatment, efficiency is enhanced due to the hole transport material further adhering to a porous electrode.

There is no restriction regarding a press treatment method and may be a press forming method employing a flat plate as represented by an immediate-release (IR) tablet shaper and a roll press method employing a roller. It is preferable that the pressure is approximately 10 kgf/cm² or more, and more preferably approximately 30 kgf/cm² or more. There is no restriction regarding press time of the press treatment. Preferably, press time is approximately 1 hour or less. In addition, heat may be applied when conducting press treatment. A release material may be sandwiched between a press machine and an electrode. Specific examples of the release material include, but are not limited to, fluororesins such as polytetrafluoroethylene, polychlorotrifluoroethylene, tetrafluoroethylene-hexafluoropropylene copolymer, perfluoroalkoxyfluoro resin, polyvinylidene fluoride, ethylene-tetrafluoroethylene copolymer, ethylene-chlorotrifluoroethylene copolymer, and polyvinyl fluoride.

After conducting the above-described press treatment, a metal oxide layer may be provided between the hole transport layer and the second electrode 9 before providing the second electrode 9. Specific examples of a metal oxide include, but are not limited to, molybdenum oxide, tungsten oxide, vanadium oxide, and nickel oxide. Among the examples, molybdenum oxide is particularly preferable.

There is no restriction regarding methods of providing the metal oxide layer on the hole transport layer and may be a method of forming a thin film in a vacuum such as sputtering and vacuum deposition, or may be a wet-type film forming method. The wet-type film forming method is preferably a method in which a paste having a sol or powder of the metal oxide or graphite is prepared, and coating the prepared paste onto the hole transport layer. The coating method in the wet-type film forming method may be the same as the coating method in the above-described electron transport layer 3.

Film thickness of the metal oxide layer is preferably in a range from approximately 0.1 nm to approximately 50 nm, and more preferably in a range from approximately 1 nm to approximately 10 nm

### <Second Electrode (Hole Collecting Electrode)>

The second electrode 9 is a hole collecting electrode and is provided on the hole transport layer or the above-described metal oxide layer. In the same way as the first electrode 2, the second electrode 9 is divided into 2A, 2B, 2C, 2D, and 2E. Generally, the second electrode 9 may be the same as the first electrode 2. A support body is not always necessary in a configuration having sufficient structural strength and sealing capability.

Specific examples of materials for the second electrode 9 include, but are not limited to, metals (e.g., platinum, gold, silver, copper, aluminum), carbon-based compounds (e.g., graphite, fullerene, carbon nanotube, graphene), conductive metal oxides (e.g., ITO, FTO, ATO), conductive polymers (e.g., polythiophene, polyaniline), and charge-transfer complexes combining an organic donor material and an organic acceptor material (e.g., tetrathiafulvalene-tetracyanoquinodimethane). The above-described materials for the second electrode 9 may be used alone or in a combination of two or more types. There is no restriction regarding thickness of the second electrode 9.

According to the employed type of material or type of the hole transport layer, the second electrode 9 may be formed with methods such as coating, lamination, deposition, chemical vapor deposition (hereinafter referred to as CVD), and bonding.

For a solar cell configuration to operate as a solar cell, at least either the first electrode 2 or the second electrode 9 has to be essentially transparent.

In the configuration of the solid dye sensitization type solar cell according to an embodiment of the present invention, the first electrode 2 is transparent. Preferably, sunlight incidence is from the first electrode 2 side. In the configuration of the solid dye sensitization type solar cell, it is preferable that a light reflecting material is employed for the second electrode 9. Preferably, the light reflecting material is metal, glass having deposition of a conductive oxide, plastic, or metal thin film.

In addition, providing a reflection preventing layer at the side of sunlight incidence is also advantageous.

### <Solar Cell and Secondary Battery Combination>

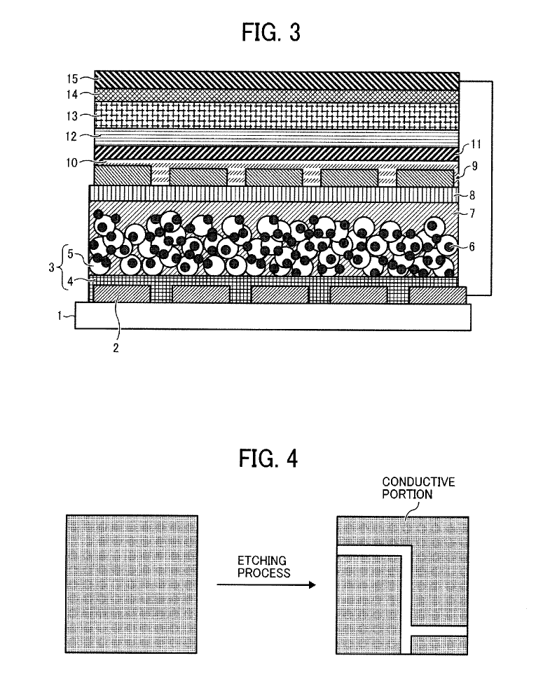

A configuration of a solid dye sensitization type solar cell module according to an embodiment of the present invention having a combination of the solid dye sensitization type solar cell and a secondary battery (semiconductor battery) is described in the following with reference to FIG. 3. FIG. 3 is a cross-sectional view of an example of the solid dye sensitization type solar cell module.

In the example, the solid dye sensitization type solar cell is configured of the first electrode 2 provided on the substrate 1; the electron transport layer 3 formed of the compact electron transport layer 4 and the porous electron transport layer 5 provided on the first electrode 2 and the substrate 1; a photosensitizing compound 6 adsorbed on the porous electron transport layer 5; and the first hole transport layer 7, the second hole transport layer 8, and the second electrode 9 provided on the electron transport layer 3 including the adsorbed photosensitizing compound 6. The order of configuration is as described above. The semiconductor battery is laminated on the solid dye sensitization type solar cell via an insulation layer 10. The semiconductor battery is configured of a first electrode 11 of the semiconductor battery, an electron transport layer 12 of the semiconductor battery, a charge layer 13, a hole transport layer 14 of the semiconductor battery, and a second electrode 15 of the semiconductor battery. The order of configuration is as described above. The second electrode 9 of the solid dye sensitization type solar cell and the first electrode 11 of the semiconductor battery are connected. The first electrode 2 of the solid dye sensitization type solar cell and the second electrode 15 of the semiconductor battery are connected.

By employing the above-described configuration, a practical solid dye sensitization type solar cell module is obtained.

### EXAMPLES

Further understanding can be obtained by reference to specific examples, which are provided hereinafter. However, it is to be understood that the embodiments of the present invention are not limited to the following examples.

### Example 1

As shown in FIG. 4, an ATO substrate (from Geomatic Co. Ltd.) is subjected to an etching process. A combined solution of 2 mL of titanium tetra-n-propoxide, 4 mL of acetic acid, 1 mL of ion exchanged water, and 40 mL of 2-propanol is spin coated onto the ATO substrate and dried at room temperature. After drying, the coated ATO substrate is fired at 450° C. in air for 30 minutes. Accordingly, a compact electron transport layer having a thickness of approximately 100 nm is formed on the ATO substrate serving as an electrode.

Next, 3 g of titanium oxide (ST-21from Ishihara Sangyo Kaisha, Ltd.), 0.2 g of acetylacetone, 0.3 g of a surface-active agent (polyoxyethyleneoctylphenyl ether from Wako Pure Chemical Industries, Ltd.), 5.5 g of water, and 1.0 g of ethanol is subjected to a bead mill process for twelve hours to obtain a dispersion liquid. 1.2 g of polyethylene glycol (#20,000) is added to the obtained dispersion liquid and a paste is prepared.

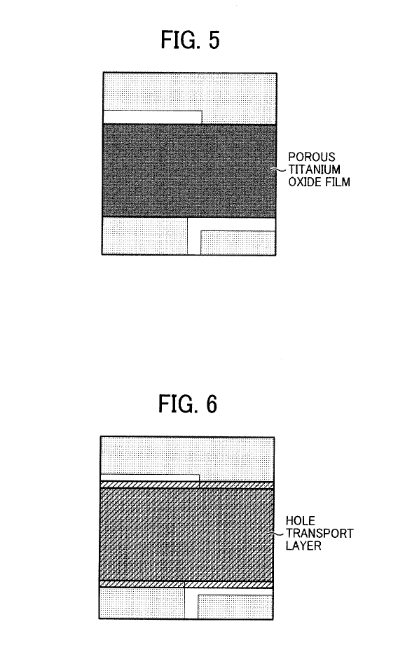

As shown in FIG. 5, the paste is coated onto the compact electron transport layer to form a film having a thickness of approximately 2μm and dried at room temperature. After drying, the coated compact electron transport layer is fired at 500° C. in air for 30 minutes. Accordingly, a porous titanium oxide film serving as a porous electron transport layer is formed. The ATO substrate having the compact electron transport layer and the porous electron transport layer is immersed in a combined solution of acetonitrile/t-butanol (volume ratio 1:1), and left in a dark place for fifteen hours at room temperature to adsorb a photosensitizing compound.

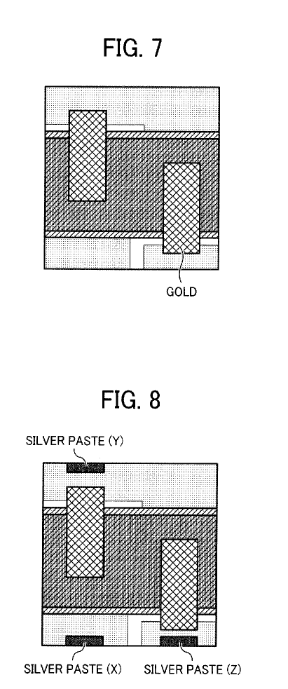

Next, a solution of 27 mM of trifluoromethanesulfonylimide lithium and 0.11 mM of 4-t-butylpyridine added to a chlorobenzene (solid content 10% by weight) solution having dissolved following Compound 1 is prepared. The solution is spin coated onto the porous electron transport layer with the adsorbed photosensitizing compound. Accordingly, a first hole transport layer is formed as shown in FIG. 6. Next, a solution of 27 mM of trifluoromethanesulfonylimide lithium added to chlorobenzene (solid content 2% by weight) having dissolved poly(3-n-hexylthiophene) is prepared. The solution is coated onto the first hole transport layer by spraying. Accordingly, a second hole transport layer is formed as shown in FIG. 6. As shown in FIG. 7, 100 nm of gold serving as a second electrode is provided on the second hole transport layer by vacuum deposition. Two cells are connected in series.

Next, a silver paste is coated on the ATO substrate at positions X, Y, and Z shown in FIG. 8 and air dried. Thus, a solid dye sensitization type solar cell of Example 1 is prepared.

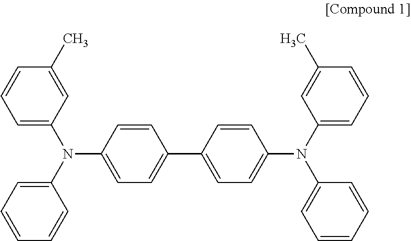 [SMILES: Cc1cccc(N(c2ccccc2)c2ccc(-c3ccc(N(c4ccccc4)c4cccc(C)c4)cc3)cc2)c1]

Employing a solar simulator, pseudo sunlight (Air mass coefficient 1.5, 100 mW/cm²) is irradiated on the solid dye sensitization type solar cell and voltage increase of the solid dye sensitization type solar cell connected in series is measured. Between positions X and Y, an open-circuit voltage is 0.79 V. Between positions Y and Z, an open-circuit voltage is 0.80 V. Between positions Z and X, an open-circuit voltage is 1.59 V. Thus, an open-circuit voltage of two times is exhibited without dividing the electron transport portion and the hole transport portion. Accordingly, it can be understood that the solid dye sensitization type solar cell of Example 1 according to an embodiment of the present invention is operating connected in series.

### Example 2

A solid dye sensitization type solar cell of Example 2 having five cells connected in series with the configuration shown in FIG. 1 is prepared. The employed materials are the same as Example 1. The first electrodes and the second electrodes are connected as follows: the first electrode 1A and the second electrode 2B; the first electrode 1B and the second electrode 2C; the first electrode 1C and the second electrode 2D; and the first electrode 1D and the second electrode 2E.

The procedure of irradiating pseudo sunlight with the solar simulator as in Example 1 is repeated. The pseudo sunlight is irradiated on the solid dye sensitization type solar cell of Example 2 and voltage increase is measured. An open-circuit voltage of 4.05 V is obtained. An open-circuit voltage of approximately 0.8 V is obtained from a single cell. Accordingly, it can be understood that, due to five cells connected in series, an open-circuit voltage of five times is obtained.

### Example 3

A solid dye sensitization type solar cell of Example 3 having cells connected in series as in Example 1 except for replacing the Compound 1 with the following Compound 2 is prepared.

The procedure of irradiating pseudo sunlight with the solar simulator as in Example 1 is repeated. The pseudo sunlight is irradiated on the solid dye sensitization type solar cell of Example 3 and voltage increase is measured. An open-circuit voltage of 1.60 V is obtained. An open-circuit voltage of approximately 0.8 V is obtained from a single cell. Accordingly, it can be understood that the solid dye sensitization type solar cell of Example 3 is operating connected in series in the same way as Example 1.

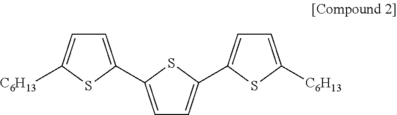

### Example 4

A solid dye sensitization type solar cell of Example 4 having cells connected in series as in Example 1 except for replacing 27 mM of trifluoromethanesulfonylimide lithium with 1-methyl-3-ethylimidazolinium trifluoromethanesulfonylimide is prepared.

The procedure of irradiating pseudo sunlight with the solar simulator as in Example 1 is repeated. The pseudo sunlight is irradiated on the solid dye sensitization type solar cell of Example 4 and voltage increase is measured. An open-circuit voltage of 1.60 V is obtained. An open-circuit voltage of approximately 0.8 V is obtained from a single cell. Accordingly, it can be understood that the solid dye sensitization type solar cell of Example 4 is operating connected in series in the same way as Example 1.

### Example 5

A solid dye sensitization type solar cell of Example 5 having cells connected in series as in Example 1 except for replacing titanium oxide (ST-21 from Ishihara Sangyo Kaisha, Ltd.) with zinc oxide (from C.I. Kasei. Co., Ltd.) is prepared.

The procedure of irradiating pseudo sunlight with the solar simulator as in Example 1 is repeated. The pseudo sunlight is irradiated on the solid dye sensitization type solar cell of Example 5 and voltage increase is measured. An open-circuit voltage of 1.40 V is obtained. An open-circuit voltage of approximately 0.7 V is obtained from a single cell. Accordingly, it can be understood that the solid dye sensitization type solar cell of Example 5 is operating connected in series in the same way as Example 1.

### Example 6

A secondary battery (semiconductor battery) that is charged with electricity generated by the solid dye sensitization type solar cell is manufactured as follows.

ITO is sputtered on a glass substrate to form a first electrode having 200 nm thickness. A solution of 0.24 g of tin 2-ethythexanoate and 1.2 g of silicone oil (TSF433) dissolved in 1.28 mL of toluene is prepared. The solution is spin coated onto the first electrode and air dried. After drying, the first electrode coated with the solution is fired at 500° C. for one hour. Accordingly, a film is obtained. The obtained film is irradiated with an ultraviolet ray having 254 nm wavelength at an intensity of 40 mW/cm² for five hours. Next, nickel oxide is sputtered to form a nickel oxide layer having 150 nm thickness on the film and ITO is sputtered on the nickel oxide layer to form a second electrode having 200 nm thickness. Thus, a semiconductor battery is prepared. The second electrode of the solid dye sensitization type solar cell of Example 2 is connected to the first electrode of the semiconductor battery with an alligator clip. The first electrode of the solid dye sensitization type solar cell of Example 2 is connected to the second electrode of the semiconductor battery with an alligator clip. Thus, an integrated module of Example 6 combining the solid dye sensitization type solar cell of Example 2 and the semiconductor battery is prepared. The integrated module is evaluated as follows.

The integrated module, in a state of an open-circuit, is irradiated with a pseudo sunlight from the first electrode side of the solid dye sensitization type solar cell of Example 2. Accordingly, when a photoelectromotive force of the first electrode of the solid dye sensitization type solar cell of Example 2 is measured during irradiation, a generation of a negative electromotive force by a photo-electrode (i.e., the first electrode of the solid dye sensitization type solar cell of Example 2) with respect to a counter electrode is confirmed. In other words, due to pseudo sunlight irradiation, reduction of an electrode active material constituting the photo-electrode occurs and the semiconductor battery is charged. Pseudo sunlight irradiation of the photo-electrode is continued until saturation of the voltage of the photo-electrode is confirmed. When confirmed, pseudo sunlight irradiation is stopped and charging of the semiconductor battery is ended.

After charging of the semiconductor battery is ended, the semiconductor battery is placed in a dark place. In a state in which an external circuit is closed, output voltage of the semiconductor battery is measured with a potentiostat. An output voltage of 1.7 V is obtained. In addition, when the photo-electrode is a negative electrode and the counter electrode is a positive electrode, and discharging is conducted at a constant current density of 10 μA/cm², a discharge capacity of 0.533 μAh/cm² is obtained.

### Comparative Example 1

An integrated module of Example 6 except for the solid dye sensitization type solar cell of Example 2 replaced with a solid dye sensitization type solar cell configured of a single cell (open-circuit voltage 0.79 V) without electrode division is prepared. Charging of a secondary battery (semiconductor battery) is conducted as in Example 6. The semiconductor battery could not be charged. The output voltage of the semiconductor battery is 1.7 V. The open-circuit voltage of a single cell is 0.79 V. Thus, the voltage is insufficient to conduct charging.

From the above results, it can be understood that the solid dye sensitization type solar cell according to an embodiment of the present invention exhibit series connection by electrode division, and may be easily manufactured. Further, the solid dye sensitization type solar cell module according to an embodiment of the present invention exhibit good charge/discharge capability by combining the solid dye sensitization type solar cell and the secondary battery (semiconductor battery).

The solid dye sensitization type solar cell according to an embodiment of the present invention includes the substrate, the first electrode, the electron transport layer configured of an electron transport semiconductor having the photosensitizing compound adsorbed on the electron transport semiconductor surface, the hole transport layer, and the second electrode. The first electrode and the second electrode are configured of divided multiple electrodes, respectively.

The hole transport layer includes at least a metal salt of perfluoro alkylsulfonyl imide anion or an ion liquid configured of perfluoro alkylsulfonyl imide anion and imidazole cation.

The hole transport layer is configured of at least one type of tertiary amine compound or thiophene compound.

The electron transport semiconductor is an oxide semiconductor.

The oxide semiconductor is at least one type of titanium oxide, zinc oxide, tin oxide, and niobium oxide.

The solid dye sensitization type solar cell module includes the solid dye sensitization type solar cell and the secondary battery. The solid dye sensitization type solar cell is connected to the secondary battery.

What s claimed is:

1. A solid dye sensitization type solar cell, comprising:
a substrate;
a first electrode disposed on the substrate;
an electron transport layer including an electron transport semiconductor and disposed on the first electrode, the electron transport layer including a photosensitizing compound adsorbed on a surface of the electron transport semiconductor;
a hole transport layer disposed on the electron transport layer; and
a second electrode disposed on the hole transport layer;
wherein each of the first electrode and the second electrode includes divided multiple electrodes.

2. The solid dye sensitization type solar cell of claim 1, wherein the hole transport layer includes at least one of a metal salt of perfluoro alkylsulfonyl imide anion and an ion liquid including perfluoro alkylsulfonyl imide anion and imidazole cation.

3. The solid dye sensitization type solar cell of claim 1, wherein the hole transport layer includes at least one type of tertiary amine compound and thiophene compound.

4. The solid dye sensitization type solar cell of claim herein the electron transport semiconductor is an oxide semiconductor.

5. The solid dye sensitization type solar cell of claim 4, wherein the oxide semiconductor includes at least one type of titanium oxide, zinc oxide, tin oxide, and niobium oxide.

6. A solid dye sensitization type solar cell module, comprising:
a secondary battery; and
the solid dye sensitization type solar cell of claim 1,
wherein the secondary battery is connected to the solid dye sensitization type solar cell of claim 1.
